(19) United States
(12) Patent Application Publication
(10) Pub. No.: US 2026/0157165 A1
(43) Pub. Date: Jun. 4, 2026

(54) SEMICONDUCTOR DEVICE AND METHOD FOR MANUFACTURING SEMICONDUCTOR DEVICE

(71) Applicant: TAKAHIRO KAMEI

(72) Inventor: TAKAHIRO KAMEI

(21) Appl. No.: 18/040,273

(22) PCT Filed: Jun. 18, 2021
(86) PCT No.: PCT/JP2021/023188

§ 371 Date: Feb. 2, 2023

(51) Int. Cl. H10W 20/20; H10W 10/00; H10W 10/17; H10W 20/00

(52) U.S. Cl. CPC H10W 20/2134; H10W 10/014; H10W 10/17; H10W 20/0234; H10W 20/0257; H10W 20/2125

(57) ABSTRACT

Provided are a semiconductor device and a method for manufacturing the semiconductor device that suppress variations in the film thickness of side walls of TSVs and improve the coverage of an opening in a high-aspect structure. A semiconductor device includes a through-electrode having a resin ISO structure using a ring TSV, the through-electrode including: a blind hole formed by excavating a semiconductor substrate to a metal pad laminated on an insulating layer; a photosensitive insulating film covering an upper surface of the semiconductor substrate and an inner peripheral surface of the blind hole; and a conductive metal covering the insulating film, wherein the ring TSV is formed such that an opening diameter of an upper stage is slightly different from an inner diameter of a lower stage.

### TECHNICAL FIELD

The present disclosure relates to a semiconductor device having a resin ISO (isolation) structure using a ring TSV of the semiconductor device and a method for manufacturing the semiconductor device.

### BACKGROUND ART

Conventionally, Si through-electrodes (Through Silicon Via, hereinafter referred to as “TSV”), which are electrodes penetrating vertically through a semiconductor substrate in the thickness direction, have been used as a three-dimensional mounting technology that accompanies the high functionality and high integration of semiconductor devices.

The TSV is formed by forming a through-hole through a silicon substrate to reach a connection target electrode or a vicinity thereof, forming an insulating film on the periphery and the inner surface of the through-hole, removing the insulating film laminated on the bottom of the through-hole to open the through-hole toward the connection target electrode, and embedding a barrier metal film and metal in the through-hole to form an electrode.

Such through-electrodes are used for electrically connecting various devices that are three-dimensionally laminated in order to achieve miniaturization and high density. Along with this, PTL 1 and 2 are disclosed as related arts of a semiconductor device having a through-electrode with a thermomechanical reliability and high connection reliability and a method for manufacturing the same at a low cost.

PTL 1 discloses a through-electrode and a semiconductor device, the through-electrode formed in a semiconductor substrate with an insulating layer interposed therebetween, and including a conductive core layer and a cylindrical semiconductor layer formed between the core layer and the insulating layer and containing the same material as the semiconductor substrate. PTL 1 also discloses a method for manufacturing the through-electrode and the semiconductor device, including: forming a cylindrical groove in a semiconductor substrate; embedding an insulating layer in the groove; forming a through-hole inside the insulating layer and forming a cylindrical semiconductor layer composed of a part of the semiconductor substrate between the insulating layer and the through-hole; and embedding a conductive material in the through-hole to form a core layer.

PTL 2 discloses a semiconductor device and a method for manufacturing the same including: removing an insulating film on an I/O pad while leaving the insulating film on a wall surface and a second surface of a two-stage through-hole, forming a through-electrode on the I/O pad and the wall surface of the two-stage through-hole using a metal film, and forming a wiring pattern on a second surface so as to be connected to the through-electrode. Specifically, a first hole having a bottom at a predetermined position in a thickness direction from the second surface side of the semiconductor substrate is formed in a tapered shape in which the diameter of the opening becomes smaller toward the bottom of the hole, The two-stage through-hole is formed by forming a cylindrical second hole reaching the I/O pad on the first surface side from the first hole. An inorganic insulating film is formed on the wall surface of the two-stage through-hole and the second surface. After that, the entire surface of the insulating film is dry-etched.

### CITATION LIST

### Patent Literature

[PTL 1]
JP 2016-213349 A
[PTL 2]
JP 2013-140916 A

### SUMMARY

### Technical Problem

However, the technology related to the through-electrode, the semiconductor device, and the manufacturing method thereof disclosed in PTL 1 has a problem that the electrode coverage deteriorates when the aspect ratio is large because the insulating layer and the silicon are formed flush with each other.

The technology related to the semiconductor device and the manufacturing method thereof disclosed in PTL 2 has a problem that embedding is difficult when the aspect ratio is large, and voids and the like are generated in the inorganic material, resulting in embedding failure.

The present disclosure has been made in view of the above-described problems, and an object thereof is to provide a semiconductor device and a method for manufacturing the semiconductor device that suppress variations in the film thickness of side walls of TSVs and improve the coverage of an opening in a high-aspect structure.

### Solution to Problem

The present disclosure has been made to solve the above-described problems, and a first aspect of the present disclosure provides a semiconductor device including a through-electrode having a resin ISO structure using a ring TSV, the through-electrode including: a blind hole formed by excavating a semiconductor substrate to a metal pad laminated on an insulating layer; a photosensitive insulating film covering an upper surface of the semiconductor substrate and an inner peripheral surface of the blind hole; and a conductive metal covering the insulating film, wherein the ring TSV is formed such that an opening diameter of an upper stage is slightly different from an inner diameter of a lower stage. The term “resin ISO structure” refers to an isolation structure in which a resin is used for an insulating film or the like.

A second aspect provides a semiconductor device including a through-electrode having a resin ISO structure using a ring TSV, the through-electrode including: a blind hole formed by excavating a semiconductor substrate to a metal pad laminated on an insulating layer; a photosensitive insulating film covering an upper surface of the semiconductor substrate and an inner peripheral surface of the blind hole; and a conductive metal covering the insulating film, wherein the ring TSV is formed such that a semiconductor layer is interposed between the insulating film and the conductive metal.

Moreover, in this first or second aspect, the through electrode may be a stepped hole formed such that an opening diameter of the upper stage is slightly larger than an inner diameter of the lower stage.

Further, in the first aspect, the through-electrode may be a hole with eaves formed such that an opening diameter of the upper stage is slightly smaller than an inner diameter of the lower stage.

Further, in the first or second aspect, the through-electrode may be a tapered hole in which the upper stage is tapered.

In the first or second aspect, the insulating film having photosensitivity may be made of a resin of an organic material or an inorganic material.

A third aspect provides a method for manufacturing a semiconductor device having a resin ISO structure using a ring TSV, including: removing a resist applied to an upper surface of a semiconductor substrate in a substantially ring shape in plan view by ring TSV lithography; performing ring TSV etching on a portion from which the resist has been removed to form a ring through-hole having a substantially cylindrical shape in plan view; applying an insulating film to the upper surface of the semiconductor substrate in which the ring through-hole is formed, and filling an insulating film in the ring through-hole; forming an opening of the ring through-hole into a predetermined shape by lithography; removing a semiconductor pillar formed by being surrounded by the insulating film filled in the ring through-hole by TSV etching to form a through-hole; and forming a through-electrode by covering an inner peripheral surface of the through-hole with a conductive material.

By adopting the above-described aspects, variations in the film thickness of the side walls of the TSV can be suppressed, the coverage of an opening in a high-aspect structure can be improved, and the propagation delay time of electrical signals can be reduced, enabling high-speed transmission.

### BRIEF DESCRIPTION OF DRAWINGS

FIG. 1 is a plan view of a resin ISO structure using a ring TSV according to a first embodiment, and a cross-sectional view taken along line U-U or a view corresponding thereto.

FIG. 2 is a plan view of a resin ISO structure using a ring TSV according to a second embodiment, and a cross-sectional view taken along line V-V or a view corresponding thereto.

FIG. 3 is a plan view of a resin ISO structure using a ring TSV according to a third embodiment, and a cross-sectional view taken along line W-W or a view corresponding thereto.

FIG. 4 is a plan view of a resin ISO structure using a ring TSV according to a fourth embodiment, and a cross-sectional view taken along line X-X or a view corresponding thereto.

FIG. 5 is a plan view of a resin ISO structure using a ring TSV according to a fifth embodiment, and a cross-sectional view taken along line Y-Y or a view corresponding thereto.

FIG. 6 is a plan view of a resin ISO structure using a ring TSV according to a sixth embodiment, and a cross-sectional view taken along line Z-Z or a view corresponding thereto.

FIG. 7 is a diagram showing processes up to a resist removal step in a method for manufacturing a resin ISO structure using a ring TSV according to the first and second embodiments.

FIG. 8 is a diagram showing processes up to a TSV etching step in a method for manufacturing a resin ISO structure using a ring TSV according to the first and second embodiments.

FIG. 9 is a diagram showing processes up to a Cu etching step in a method for manufacturing a resin ISO structure using a ring TSV according to the first and second embodiments.

FIG. 10 is a diagram showing processes up to a resist removal step in a method for manufacturing a resin ISO structure using a ring TSV according to the third embodiment.

FIG. 11 is a diagram showing processes up to a TSV interlayer film etching step in a method for manufacturing a resin ISO structure using a ring TSV according to the third embodiment.

FIG. 12 is a diagram showing processes up to a Cu etching step in a method for manufacturing a resin ISO structure using a ring TSV according to the third embodiment.

FIG. 13 is a diagram showing processes up to a TSV etching step in a method for manufacturing a resin ISO structure using a ring TSV according to the fourth and fifth embodiments.

FIG. 14 is a diagram showing processes up to a resist removal step of etching the ring TSV in the method for manufacturing the resin ISO structure using the ring TSV according to the fourth and fifth embodiments.

FIG. 15 is a diagram showing processes up to a TSV etching step in a method for manufacturing a resin ISO structure using a ring TSV according to the fourth and fifth embodiments.

FIG. 16 is a diagram showing processes up to a Cu etching step in a method for manufacturing a resin ISO structure using a ring TSV according to the fourth and fifth embodiments.

FIG. 17 is a diagram showing processes up to a TSV etching step in a method for manufacturing a resin ISO structure using a ring TSV according to the sixth embodiment.

FIG. 18 is a diagram showing processes up to an etching resist removal step of the ring TSV in a method for manufacturing a resin ISO structure using a ring TSV according to the sixth embodiment.

FIG. 19 is a diagram showing processes up to a TSV interlayer film etching step of an insulating film in a method for manufacturing a resin ISO structure using a ring TSV according to the sixth embodiment.

FIG. 20 is a diagram showing processes up to a Cu etching step in a method for manufacturing a resin ISO structure using a ring TSV according to the sixth embodiment.

FIG. 21 is a plan view showing insulating-film through-holes according to the third embodiment and the sixth embodiment.

### DESCRIPTION OF EMBODIMENTS

Modes for implementing the present disclosure (hereinafter referred to as embodiments) will be described below with reference to the drawings. In the following drawings, the same or similar parts are denoted by the same or similar reference signs. However, the drawings are schematic, and the dimensional ratios and the like of respective parts are not necessarily consistent with actual ones. Furthermore, the drawings of course include parts where dimensional relationships and ratios differ among drawings.
1. Basic configuration example and modification example of first embodiment
2. Basic configuration example and modification example of second embodiment
3. Third embodiment
4. Basic configuration example and modification example of fourth embodiment
5. Basic configuration example and modification example of fifth embodiment
6. Sixth embodiment
7. Manufacturing method according to first and second embodiments
8. Manufacturing method according to third embodiment
9. Manufacturing method according to fourth and fifth embodiments
10. Manufacturing method according to sixth embodiment

### 1. Basic Configuration Example and Modification Example of First Embodiment

### [Basic Configuration Example of First Embodiment]

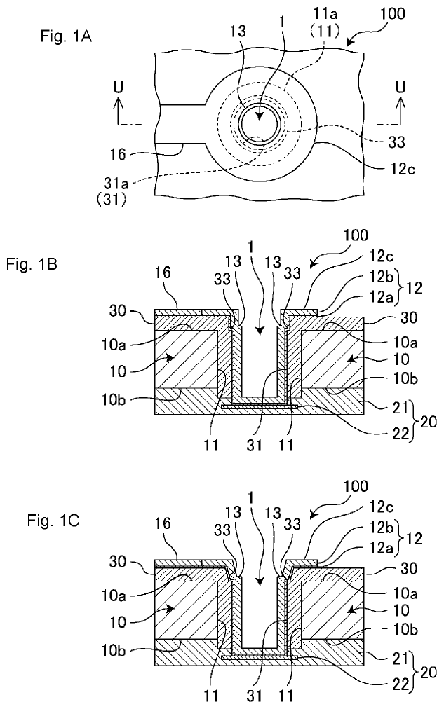

FIG. 1A is a plan view of a resin ISO structure using a ring TSV according to the basic configuration example of the first embodiment. However, the description of the parts below a semiconductor substrate 10 is omitted (the same applies hereinafter). FIG. 1B is a cross-sectional view taken along line U-U in FIG. 1A. Note that the ring TSV can be, for example, cylindrical.

As shown in FIG. 1B, the semiconductor device 100 is provided with a wiring layer 20 including an insulating layer 21, a copper pad 22, transistor elements (not shown), and the like, on a lower surface 10b of the semiconductor substrate 10 such as a silicon substrate. In actual manufacturing, however, the wiring layer 20 is turned upside down after being laminated on the upper layer of the semiconductor substrate 10, so that it is positioned on the lower surface 10b of the semiconductor substrate 10 as shown in FIG. 1B.

The wiring layer 20 has an insulating layer 21 and a copper pad 22 in addition to transistor elements and the like. The copper pad 22 is arranged close to the lower surface 10b of the semiconductor substrate 10 and forms an electrode in the wiring layer 20. Although only the insulating layer 21 and the copper pads 22 are shown in FIG. 1B, other insulating layers 21 and copper pads 22 may be present.

As shown in FIG. 1B, a substrate through-hole 11 that vertically penetrates the semiconductor substrate 10 is formed in the semiconductor substrate 10. That is, the substrate through-hole 11 penetrates the semiconductor substrate 10 from the upper surface 10a to the opposite lower surface 10b, and is further excavated to the copper pad 22 of the wiring layer 20 to form a blind hole having the copper pad 22 as the bottom of the hole. The substrate through-hole 11 is a high-aspect ratio through-hole whose depth is longer than the opening diameter thereof.

Although not shown in this figure, the substrate through-hole 11 may be excavated further below the copper pad 22 of the wiring layer 20 so as to reach another copper pad 22 formed below the copper pad 22. That is, a part of the substrate through-hole 11 may include a recess or a through-hole formed in the copper pad 22.

An insulating film 30 is continuously formed on the entire surface of the semiconductor substrate 10 along the inner peripheral surface of the substrate through-hole 11 and the upper surface 10a of the semiconductor substrate 10 (at least around the opening of the substrate through-hole 11 on the upper surface 10a). That is, the insulating film 30 covers, with a substantially constant thickness, the inner peripheral surface of the substrate through-hole 11 formed in the semiconductor substrate 10, the inner peripheral surface of the substrate through-hole 11 formed by excavating the insulating layer 21 to a predetermined depth, and the upper surface 10a of the semiconductor substrate 10. However, the copper pad 22 or the insulating layer 21 forming the bottom of the substrate through-hole 11 is not covered with the insulating film 30.

The insulating film 30 is a film having photosensitivity and is made of an organic resin or an organic/inorganic hybrid material. That is, since the insulating film 30 has photosensitivity, lithographic processing can be performed directly without applying a resist 40. The photosensitivity of the insulating film 30 may be either positive type or negative type.

As described above, the inner peripheral surface and the like of the substrate through-hole 11 are covered with the insulating film 30. By covering in this way, the hole diameter of the substrate through-hole 11 is reduced by twice the film thickness of the insulating film 30. An insulating-film through-hole 31 is formed in the substrate through-hole 11 by covering the inner peripheral surface of the substrate through-hole 11 with the insulating film 30.

As shown in FIG. 1B, the insulating-film through-hole 31 is provided with a step 33 by widening the opening 31a to a predetermined depth by a predetermined diameter by lithography. Thus, the insulating-film through-hole 31 formed by covering the inner peripheral surface and the like of the substrate through-hole 11 with the insulating film 30 forms a stepped hole.

The step 33 is formed to a predetermined depth from the opening 31a, for example, to a depth substantially equal to the thickness of the insulating film 30 covering the opening 31a. That is, the step 33 is positioned above the insulating-film through-hole 31. Further, the diameter of the upper stage of the step 33 is larger than the diameter of the lower stage by several nanometers to several tens of nanometers. The difference between the diameters of the upper stage and the diameter of the lower stage is the same in other embodiments described below.

The insulating-film through-hole 31 is further covered with a metal film 12 of copper around the opening 31a and the entire inner peripheral surfaces of the upper and lower stages of the stepped hole. Specifically, as shown in FIG. 1A, at least the periphery of the opening 31a of the insulating-film through-hole 31 on the upper surface 30a of the insulating film 30, the inner peripheral surface of the upper stage of the stepped hole of the insulating-film through-hole 31, the inner peripheral surface of the step 33, the inner peripheral surface of the lower stage of the stepped hole, and the copper pad 22 of the wiring layer 20 which is the bottom of the insulating-film through-hole 31 are covered with the metal film 12 of copper, which is a conductive metal. In this manner, the entire inner peripheral surface of the insulating-film through-hole 31 is covered with the metal film 12 of copper.

The metal film 12 is composed of a conductive layer 12a formed by Seed Cu sputtering (seed copper sputtering) and a conductive layer 12b formed on the upper surface of the conductive layer 12a by Cu plating (copper plating). That is, first, Seed Cu sputtering is performed on the inner peripheral surface of the insulating-film through-hole 31 formed in the insulating film 30 to deposit a Cu seed film by sputtering to form the conductive layer 12a. Next, Cu plating is performed to further form a conductive layer 12b on the upper surface of the conductive layer 12a.

As described above, the through-electrode 1 is formed by covering the periphery of the opening 31a of the insulating-film through-hole 31 and the upper and lower stages of the inner peripheral surface with the metal film 12 composed of the conductive layers 12a and 12b. That is, a stepped hole having a step 13 covered with a metal film 12 having a shape similar to the insulating-film through-hole 31 is formed in the insulating-film through-hole 31.

As shown in the plan view of FIG. 1A, the opening 31a of the insulating-film through-hole 31 is formed with an electrode pattern 12c having a predetermined shape on the upper surface 30a of the insulating film 30. A connection conductor 16 for connecting to another electrode pattern extends from the electrode pattern 12c.

As described above, the entire inner peripheral surface and the like of the insulating-film through-hole 31 are covered with the metal film 12 of copper, and the electrode pattern 12c of the metal film 12 and the copper pad 22 of the wiring layer 20 formed around the opening 31a are electrically connected. In this way, a through-electrode 1 that vertically penetrates the semiconductor substrate 10 is formed.

Since the resin ISO structure using the ring TSV according to the basic configuration example of the first embodiment is configured as described above, the film thickness of the insulating film 30 can be easily adjusted, and the film thickness can be increased. Accordingly, it is possible to form the insulating-film through-hole 31 as a stepped hole. Moreover, since the opening 31a of the insulating-film through-hole 31 is widened by forming the stepped hole, the coverage of the through-electrode 1 in this portion can be improved. Further, when forming the through-electrode 1, it becomes easier to form the conductive layer 12a deep into the insulating-film through-hole 31 by Seed Cu sputtering.

The insulating film 30 is a film having photosensitivity, and is made of an organic resin or an organic/inorganic hybrid material. Since the insulating film 30 has photosensitivity, processing by lithography, which will be described later, can be performed directly without applying the resist 40. Moreover, since the film thickness of the insulating film 30 can be increased, the electrode coverage can be improved. Furthermore, by using a low-dielectric constant interlayer insulating film material (Low-k material) with a small relative dielectric constant such as an organic material, the capacitance between wirings can be reduced. Thus, the propagation delay time of electrical signal can be reduced, enabling high-speed transmission. Note that the effect of forming the insulating film 30 from a photosensitive material is the same in other embodiments, and thus the description will be omitted in the other embodiments.

### [Modification Example of First Embodiment]

FIG. 1C is a cross-sectional view taken along line U-U in FIG. 1A, a resin ISO structure using a ring TSV according to a modification example of the first embodiment. The resin ISO structure using the ring TSV according to this modification example is the same as the basic configuration example of the first embodiment except that the steps 33 and 13 are tapered.

In this modification example, as shown in FIG. 1C, the insulating-film through-hole 31 is provided with a step 33 in which the opening 31a is widened in a tapered manner to a predetermined depth toward the upper side by a predetermined diameter by lithography. As a result, the insulating-film through-hole 31 formed by covering the inner peripheral surface and the like of the substrate through-hole 11 with the insulating film 30 forms a stepped tapered hole. The taper angle is 60 degrees or more and less than 90 degrees with respect to the horizontal plane. The taper angle is the same below.

The configuration other than the above and the formation of the through-electrode 1 are the same as in the basic configuration example of the first embodiment, so the description thereof is omitted.

Since the resin ISO structure using the ring TSV according to this modification example is configured as described above, the film thickness of the insulating film 30 can be easily adjusted and the film thickness can be increased. Accordingly, the insulating-film through-hole 31 can be formed as a stepped tapered hole. In addition, since the opening 31a of the insulating-film through-hole 31 is widened by forming the stepped tapered hole, the coverage of the through-electrode 1 in this portion can be improved. Further, when the through-electrode 1 is formed, copper ions by Seed Cu sputtering can easily reach deep into the insulating-film through-hole 31, and the conductive layer 12a can be formed more easily.

### 2. Basic Configuration Example and Modification Example of Second Embodiment

### [Basic Configuration Example of Second Embodiment]

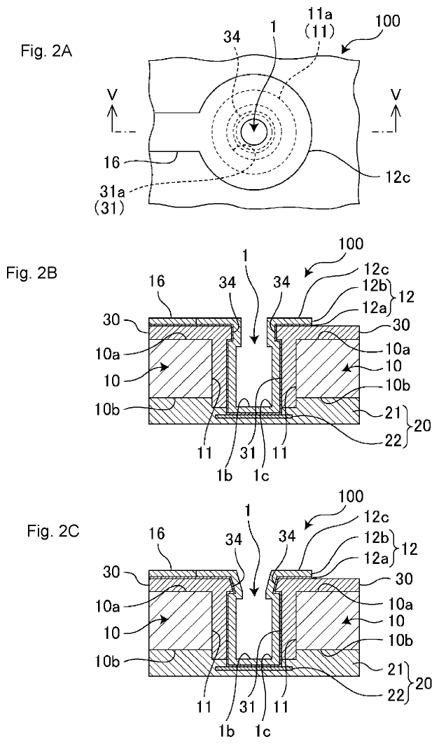

FIG. 2A is a plan view of a resin ISO structure using a ring TSV according to a basic configuration example of the second embodiment. FIG. 2B is a cross-sectional view taken along line V-V in FIG. 2A.

The resin ISO structure using the ring TSV according to the present embodiment is the same as the basic configuration example of the first embodiment, except that the steps 33 and 13 are replaced with eaves 34.

In the opening 31a of the insulating-film through-hole 31 in the present embodiment, as shown in FIG. 2B, the opening 31a is opened to a predetermined depth by a predetermined diameter by organic material lithography, and the lower stage of the opening is excavated by dry or wet etching. In this way, eaves 34 of which the upper stage protrudes from the lower stage by a predetermined diameter are formed. As a result, the insulating-film through-hole 31 formed of the insulating film 30 forms a hole with eaves formed such that the opening diameter of the upper stage is narrower than the inner diameter of the lower stage due to the eaves 34.

The configuration other than the above and the formation of the through-electrode 1 are the same as in the basic configuration example of the first embodiment, so the description thereof is omitted.

Since the resin ISO structure using the ring TSV according to the present embodiment is configured as described above, the film thickness of the insulating film 30 can be easily adjusted and the film thickness can be increased. Accordingly, it is possible to form the insulating-film through-hole 31 as a hole with eaves. Further, by forming the hole with eaves, the opening 31a of the insulating-film through-hole 31 can be narrowed, and film thickness reduction of a through-electrode bottom 1b and a through-electrode corner 1c during etch-back can be suppressed.

### [Modification Example of Second Embodiment]

FIG. 2C is a cross-sectional view taken along line V-V in FIG. 2A, of the resin ISO structure using the ring TSV according to the modification example of the second embodiment.

The resin ISO structure using the ring TSV according to this modification example is the same as the basic configuration example of the first embodiment except that tapered eaves 34 are formed instead of the steps 33 and 13.

As shown in FIG. 2C, in the opening 31a of the insulating-film through-hole 31 in this modification example, the opening 31a is opened to a predetermined depth by being widened in an upwardly tapered shape by a predetermined diameter by lithography, and the lower stage is excavated by dry or wet etching. In this way, tapered eaves 34 of which the upper stage protrudes by a predetermined diameter are formed. As a result, the opening diameter of the insulating-film through-hole 31 formed of the insulating film 30 is formed narrower than the inner diameter of the lower stage due to the tapered eaves 34. As a result, the insulating-film through-hole 31 formed by covering the inner peripheral surface and the like of the substrate through-hole 11 with the insulating film 30 forms a tapered hole with eaves.

The configuration other than the above and the formation of the through-electrode 1 are the same as in the basic configuration example of the first embodiment, so the description thereof is omitted.

Since the resin ISO structure using the ring TSV according to this modification example is configured as described above, the film thickness of the insulating film 30 can be increased, and accordingly the insulating-film through-hole 31 can be formed as a tapered hole with eaves. Further, by narrowing the opening 31a of the insulating-film through-hole 31, it is possible to suppress film thickness reduction of the through-electrode bottom 1b and the through-electrode corner 1c during etch-back. Furthermore, since the opening 31a is tapered upward, coverage of the through-electrode can be improved.

### 3. Third Embodiment

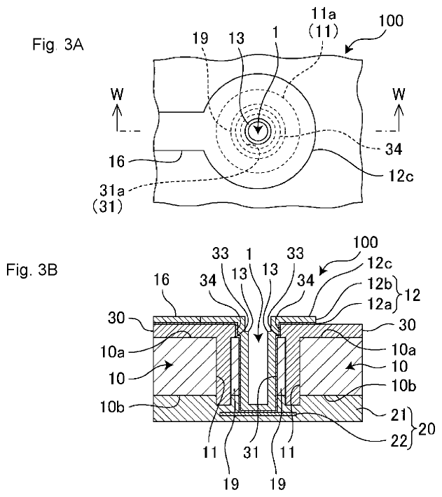

FIG. 3A is a plan view of a resin ISO structure using a ring TSV according to the third embodiment. FIG. 3B is a cross-sectional view taken along line W-W in FIG. 3A.

The resin ISO structure using the ring TSV according to the present embodiment has the same basic configuration as that of the first embodiment except that the eaves 34 are formed in the opening 31a of the insulating-film through-hole 31, and the lower stage of the eaves 34 formed in the insulating film 30 covering the inner peripheral surface of the substrate through-hole 11 is covered with the semiconductor layer 19, and the metal film 20 covers the upper side of the semiconductor layer 19.

In the present embodiment, as shown in FIG. 3B, the eaves 34 protrude from the opening 31a of the insulating-film through-holes 31, and the semiconductor layer 19 made of the same material as the semiconductor substrate 10 is interposed between the lower stage of the eaves 34 and the metal film 20 covering the inner peripheral surface of the insulating-film through-hole 31. Specifically, the opening 31a is opened to a predetermined depth by a predetermined diameter by lithography, and the lower stage is excavated by dry or wet etching. In this way, the eaves 34 protruding by a predetermined diameter are formed. The inner peripheral surface of the insulating film 30 below the eaves 34 is coaxially in close contact with the outer peripheral surface of the semiconductor layer 19 made of the same material as the semiconductor substrate 10. Further, an upper surface 15a of a ring through-hole 15 is formed flush with the upper surface 10a of the semiconductor substrate 10. Therefore, in the present embodiment, the inner peripheral surface of the lower stage of the insulating-film through-hole 31 is covered with the same material as the semiconductor substrate 10, unlike the first and second embodiments.

As described above, the inner peripheral surface and the like of the substrate through-hole 11 are covered with the insulating film 30, and the inner peripheral surface of the insulating film 30 is further covered with the semiconductor layer 19 made of the same material as the semiconductor substrate 10. That is, an insulating-film through-hole 31 whose inner peripheral surface is covered with the semiconductor layer 19 is formed in the substrate through-hole 11.

Here, since the thickness of the semiconductor layer 19 is formed thicker than the protruding length of the eaves 34, the diameter of the opening 31a of the insulating-film through-hole 31 at the upper stage above the upper surface 15a of the ring through-hole 15 is larger than that at the lower stage. Therefore, a step 33 is formed at the position of the upper surface 15a. As a result, the insulating-film through-hole 31 formed by covering the inner peripheral surface and the like of the substrate through-hole 11 with the insulating film 30 and further covering the lower stage of the step 33 with the semiconductor layer 19 in a concentric columnar shape forms a stepped hole. Note that the step 33 may be formed in a tapered shape.

The configuration other than the above and the formation of the through-electrode 1 are the same as in the basic configuration example of the first embodiment, so the description thereof is omitted.

Since the resin ISO structure using the ring TSV according to the present embodiment is configured as described above, the film thickness of the insulating film 30 can be increased, and accordingly the insulating-film through-hole 31 can be formed as a stepped hole. As a result, the opening 31a of the insulating-film through-hole 31 can be widened, and the coverage of the through-electrode 1 in this portion can be further improved. Further, when forming the through-electrode 1, it becomes easier to form the conductive layer 12a deep into the insulating-film through-hole 31 by Seed Cu sputtering. Further, since the semiconductor layer 19 is interposed and the insulating film 30 surrounding the semiconductor layer 19 is not affected even if the inner peripheral surface of the semiconductor layer 19 is excessively excavated, a large margin for dimensional deviation can be ensured in the process of forming a ring TSV hole by lithography and etching, which is advantageous for ensuring the side wall film thickness. Furthermore, the process flow can be simplified compared to the first and second embodiments described above.

### 4. Basic Configuration Example and Modification Example of Fourth Embodiment

### [Basic Configuration Example of Fourth Embodiment]

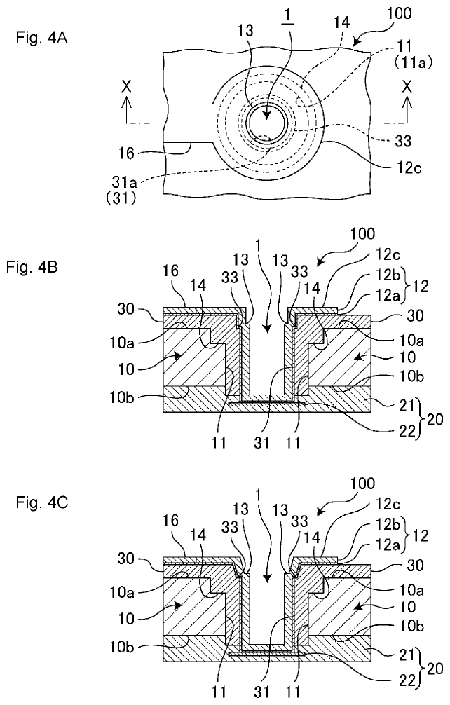

FIG. 4A is a plan view of a resin ISO structure using a ring TSV according to a basic configuration example of the fourth embodiment. FIG. 4B is a cross-sectional view taken along line X-X in FIG. 4A.

The resin ISO structure using the ring TSV according to the present embodiment is the same as the basic configuration example of the first embodiment except that a step 14 is formed in the substrate through-hole 11.

As shown in FIG. 4B, a substrate through-hole 11 that vertically penetrates the semiconductor substrate 10 is formed in the semiconductor substrate 10. That is, the substrate through-hole 11 penetrates from the upper surface 10a of the semiconductor substrate 10 to the opposite lower surface 10b, and is further excavated to the copper pad 22 of the wiring layer 20 to form a blind hole having the copper pad 22 as the bottom of the hole. The substrate through-hole 11 is a high-aspect ratio through-hole whose depth is larger than the opening diameter thereof.

Further, as shown in FIG. 4B, the opening 11a of the substrate through-hole 11 is provided with a step 14 by performing TSV etching to widen the opening 11a to a predetermined depth by a predetermined diameter. As a result, the substrate through-hole 11 forms a stepped hole.

The step 14 is formed to a predetermined depth from the upper surface 10a of the semiconductor substrate 10, for example, to a depth substantially equal to the thickness of the insulating film 30 covering the opening 11a. That is, the step 14 is positioned above the substrate through-hole 11. The insulating-film through-hole 31 is formed in the substrate through-hole 11 by covering the inner peripheral surface of the substrate through-hole 11 with the insulating film 30.

The insulating-film through-hole 31 is provided with a step 33 by widening the insulating film 30 by a predetermined diameter to a predetermined depth from the opening 31a by lithography. Thus, the insulating-film through-hole 31 formed by covering the inner peripheral surface and the like of the substrate through-hole 11 with the insulating film 30 forms a stepped hole. Since the formation of the through-electrode 1 is the same as the basic configuration example of the first embodiment described above, the description thereof will be omitted.

Since the resin ISO structure using the ring TSV according to the present embodiment is configured as described above, the film thickness of the insulating film 30 can be increased. Further, since the step 14 is provided in the opening 11a of the substrate through-hole 11, the thickness of the peripheral portion of the step 33 of the insulating-film through-hole 31 can be further increased. Thus, the coverage of the through-electrode 1 in the portion can be further improved. Other effects are the same as those of the basic configuration example of the second embodiment, so description thereof is omitted.

### [Modification Example of Fourth Embodiment]

FIG. 4C is a cross-sectional view taken along line X-X in FIG. 4A, of the resin ISO structure using the ring TSV according to the modification example of the fourth embodiment.

The resin ISO structure using the ring TSV according to this modification example is the same as the basic configuration example of the fourth embodiment except that the steps 33 and 13 are tapered.

As shown in FIG. 4C, a substrate through-hole 11 that vertically penetrates the semiconductor substrate 10 is formed in the semiconductor substrate 10 in the same manner as in the basic configuration example of the fourth embodiment. Further, the opening 11a of the substrate through-hole 11 is provided with a step 14 by performing TSV etching processing to widen the opening 11a to a predetermined depth by a predetermined diameter. Thus, the substrate through-hole 11 forms a stepped hole.

As shown in FIG. 4C, in this modification example, the insulating-film through-hole 31 is formed in the substrate through-hole 11 by covering the inner peripheral surface and the like of the substrate through-hole 11 with the insulating film 30. The insulating-film through-hole 31 is provided with the step 33 that widens the insulating film 30 in an upwardly tapered shape by a predetermined diameter from the opening 31a to a predetermined depth by lithography. As a result, the insulating-film through-hole 31 formed by covering the inner peripheral surface and the like of the substrate through-hole 11 with the insulating film 30 forms a stepped tapered hole.

The configuration other than the above and the formation of the through-electrode 1 are the same as in the basic configuration example of the first embodiment, so the description thereof is omitted.

Since the resin ISO structure using the ring TSV according to this modification example is configured as described above, the film thickness of the insulating film 30 can be increased. Further, since the step 14 is provided in the opening 11a of the substrate through-hole 11, the thickness of the peripheral portion of the step 33 of the insulating-film through-hole 31 can be further increased. Thus, the coverage of the through-electrode 1 in the portion can be further improved. Other effects are the same as those of the basic configuration example of the second embodiment, so description thereof is omitted.

### 5. Basic Configuration Example and Modification Example of Fifth Embodiment

### [Basic Configuration Example of Fifth Embodiment]

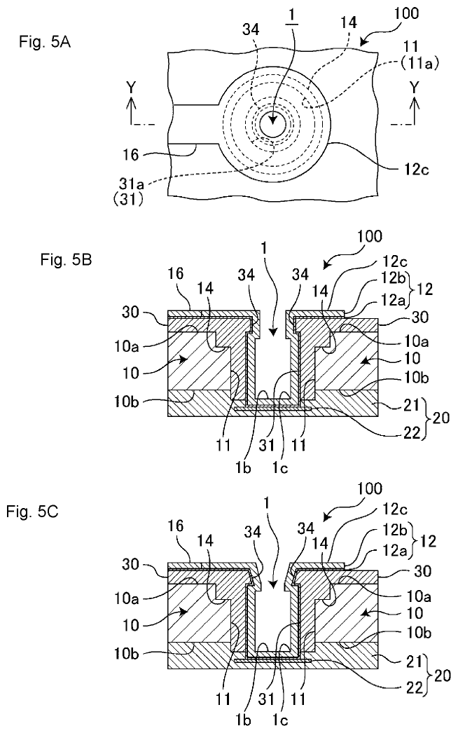

FIG. 5A is a plan view of a resin ISO structure using a ring TSV according to a basic configuration example of the fifth embodiment. FIG. 5B is a cross-sectional view taken along line Y-Y in FIG. 5A. The resin ISO structure using the ring TSV according to the present embodiment is the same as the basic configuration example of the second embodiment except that a step 14 is formed in the substrate through-hole 11.

As shown in FIG. 5C, in the present embodiment, the insulating-film through-hole 31 is formed in the substrate through-hole 11 by covering the inner peripheral surface and the like of the substrate through-hole 11 with the insulating film 30.

The insulating-film through-hole 31 is opened to a predetermined depth from the opening 31a by a predetermined diameter by lithography, and the lower stage thereof is excavated by dry or wet etching to form eaves 34 protruding by a predetermined diameter. As a result, the opening diameter of the opening 31a of the insulating-film through-hole 31 formed of the insulating film 30 is formed narrower than the inner diameter of the lower stage due to the eaves 34. As a result, the insulating-film through-hole 31 formed by covering the inner peripheral surface and the like of the substrate through-hole 11 with the insulating film 30 forms a hole with eaves.

The configuration other than the above and the formation of the through-electrode 1 are the same as in the basic configuration example of the first embodiment, so the description thereof is omitted.

Since the resin ISO structure using the ring TSV according to the present embodiment has the step 14 in the opening 11a of the substrate through-hole 11 as described above, the film thickness of the insulating film 30 can be increased. In addition, the thickness of the peripheral portion of the step 33 of the insulating-film through-hole 31 can be further increased. Thus, the coverage of the through-electrode 1 in the portion can be further improved.

### [Modification Example of Fifth Embodiment]

FIG. 5C is a cross-sectional view taken along line Y-Y in FIG. 5A, of the resin ISO structure using the ring TSV according to the modification example of the fifth embodiment.

The resin ISO structure using the ring TSV according to this modification example is the same as the basic configuration example of the fifth embodiment except that tapered eaves 34 are formed instead of the steps 33 and 13.

As shown in FIG. 5C, the substrate through-hole 11 in this modification example is formed with a step 14 similar to the basic configuration example of the fourth embodiment. An insulating-film through-hole 31 is formed in the substrate through-hole 11 by covering the inner peripheral surface thereof and the like with an insulating film 30. The insulating-film through-hole 31 is opened to a predetermined depth from the opening 31a by being widened in an upwardly tapered shape by a predetermined diameter by lithography, and the lower stage thereof is excavated by dry or wet etching to form tapered eaves 34 whose upper stage protrudes by a predetermined diameter. As a result, the opening diameter of the opening 31a of the insulating-film through-hole 31 formed of the insulating film 30 is formed narrower than the inner diameter of the lower stage due to the tapered eaves 34. As a result, the insulating-film through-hole 31 formed by covering the inner peripheral surface and the like of the substrate through-hole 11 with the insulating film 30 forms a tapered hole with eaves.

The configuration other than the above and the formation of the through-electrode 1 are the same as in the basic configuration example of the first embodiment, so the description thereof is omitted.

Since the resin ISO structure using the ring TSV according to the modification example of the fifth embodiment has the step 14 in the opening 11a of the substrate through-hole 11 as described above, the film thickness of the insulating film 30 can be increased, and accordingly the insulating-film through-hole 31 can be formed as a tapered hole with eaves. Further, by narrowing the opening 31a of the insulating-film through-hole 31, it is possible to suppress film thickness reduction of the through-electrode bottom 1b and the through-electrode corner 1c during etch-back. Furthermore, since the opening 31a is tapered upward, the coverage of the through-electrode 1 can be further improved.

### 6. Sixth Embodiment

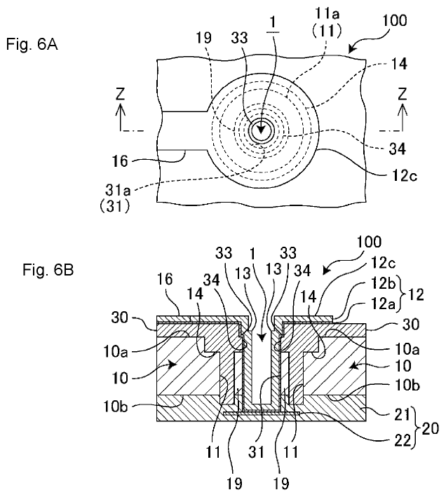

FIG. 6A is a plan view of a resin ISO structure using a ring TSV according to the sixth embodiment. FIG. 6B is a cross-sectional view taken along line Z-Z in FIG. 6A. The resin ISO structure using the ring TSV according to the present embodiment is the same as that of the third embodiment except that a step 14 is formed in the substrate through-hole 11.

In the present embodiment, as shown in FIG. 6A, the opening 31a of the insulating-film through-hole 31 has a semiconductor layer 19 interposed between the insulating film 30 covering the inner peripheral surface of the substrate through-hole 11 and the metal film 12. More specifically, the opening 31a is opened to a predetermined depth by a predetermined diameter by lithography, and the lower stage thereof is etched by dry or wet etching to form the eaves 34 protruding by a predetermined diameter. The inner peripheral surface of the insulating film 30 below the eaves 34 is coaxially in close contact with the outer peripheral surface of the semiconductor layer 19 made of the same material as the semiconductor substrate 10. Further, an upper surface 15a of a ring through-hole 15 is formed flush with the upper surface 10a of the semiconductor substrate 10. Therefore, the present embodiment is different from other embodiments except the third embodiment in the matter that the semiconductor layer 19 made of the same material as the semiconductor substrate 10 is interposed between the inner peripheral surface of the lower stage of the insulating-film through-hole 31 and the metal film 20.

As described above, the inner peripheral surface and the like of the substrate through-hole 11 are covered with the insulating film 30 which is further covered with the semiconductor layer 19 made of the same material as the semiconductor substrate 10. That is, the insulating-film through-hole 31 whose inner peripheral surface is covered with the semiconductor layer 19 is formed in the substrate through-hole 11.

Here, since the thickness of the semiconductor layer 19 is thicker than the protruding length of the eaves 34, the diameter of the opening 31a of the insulating-film through-hole 31 is larger than the inner diameter surrounded by the semiconductor layer 19 at the lower stage. Therefore, a step 33 is formed at the position of the upper surface 19a of the semiconductor layer 19. As a result, the insulating-film through-hole 31 formed by covering the inner peripheral surface and the like of the substrate through-hole 11 with the insulating film 30 and further covering the lower stage of the step 33 with the semiconductor layer 19 in a concentric columnar shape forms a stepped hole. Note that the step 33 may be formed in a tapered shape.

The configuration other than the above and the formation of the through-electrode 1 are the same as in the basic configuration example of the first embodiment, so the description thereof is omitted.

Since the resin ISO structure using the ring TSV according to the sixth embodiment has the step 14 in the opening 11a of the substrate through-hole 11 as described above, the film thickness of the insulating film 30 can be increased. In addition, the thickness of the peripheral portion of the step 33 of the insulating-film through-hole 31 can be further increased. Thus, the coverage of the through-electrode 1 in the portion can be further improved. Effects other than those described above are the same as in the case of the third embodiment, so description thereof will be omitted.

### 7. Manufacturing Method According to First and Second Embodiments

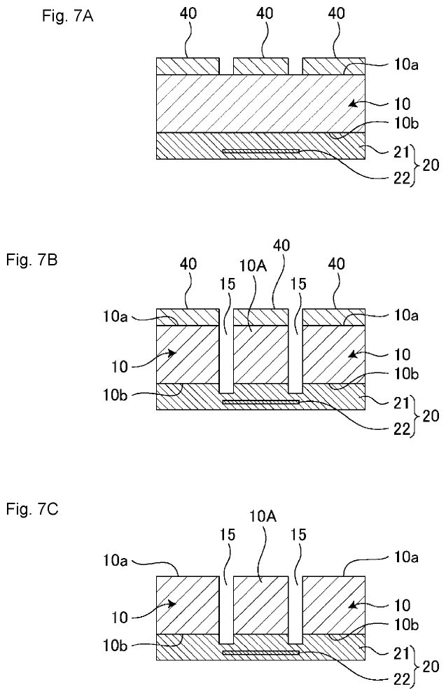

Next, the manufacturing method according to the first and second embodiments of the method for manufacturing the resin ISO structure using the ring TSV will be described with reference to FIGS. 7 to 9. First, as shown in FIG. 7A, a semiconductor substrate 10 is prepared on which a wiring layer 20 composed of an insulating film, a copper pad, transistor elements, and the like are laminated. Then, the semiconductor substrate is placed on a wafer stage of a semiconductor exposure apparatus for performing lithography. Then, a resist 40 is applied to the upper surface 10a of the semiconductor substrate 10, and the resist 40 is removed in a substantially ring shape in plan view by ring TSV lithography.

Next, as shown in FIG. 7B, ring TSV etching is performed on the portion where the resist 40 has been removed to form a ring through-hole 15 having a substantially circular shape in plan view in the semiconductor substrate 10. The ring through-hole 15 formed in this step penetrates the semiconductor substrate 10 from the upper surface 10a to the lower surface 10b and is further excavated to a predetermined depth of the insulating layer 21. However, it is assumed that the copper pad 22 is not reached.

Next, as shown in FIG. 7C, the resist 40 remaining on the upper surface 10a of the semiconductor substrate 10 is removed. As a result, a substantially cylindrical semiconductor pillar 10A surrounded by the ring through-hole 15 is formed, and the outer peripheral surface thereof forms the inner peripheral surface of the substrate through-hole 11.

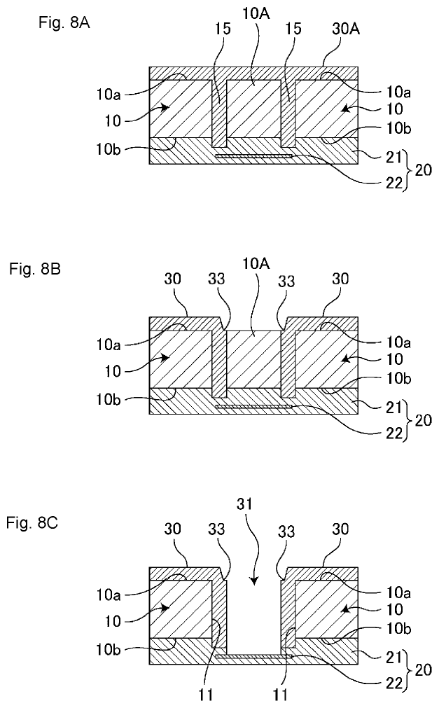

Next, as shown in FIG. 8D, a photosensitive organic material 30A for forming an insulating film 30 is filled in the ring through-hole 15 formed in the semiconductor substrate 10 by spin coating or a vacuum laminator, and the upper surface 10a of the substrate 10 is uniformly coated. Note that the organic material 30A is a resin material forming the insulating film 30.

Next, as shown in FIG. 8E, lithography is performed on the photosensitive organic material 30A applied to the upper surface 10a of the semiconductor substrate 10.

The organic material 30A filled in the ring through-hole 15 on the upper surface of the substantially cylindrical semiconductor pillar 10A formed by being surrounded by the ring through-hole 15 is removed by lithography to a diameter slightly larger than the diameter of the semiconductor pillar 10A. The peripheral surface of the opening 31a of the removed organic material 30A may be removed straight or may be removed in a tapered shape widening upward. This figure shows an example in which a tapered step 33 is provided by lithography. The organic material 30A shaped by lithography then forms the insulating film 30.

Since the organic material 30A is a photosensitive material, it has the advantage that lithography can be performed directly by exposing it to light. The photosensitive material may be of either positive type or negative type.

Next, as shown in FIG. 8F, the substantially cylindrical semiconductor pillar 10A surrounded by the organic material 30A is removed by TSV etching, and the semiconductor substrate 10 is penetrated from the upper surface 10a to the lower surface 10b. Further, the insulating-film through-hole 31 is formed by excavating the insulating layer 21 of the wiring layer 20 below the semiconductor substrate 10 to reach the copper pad 22.

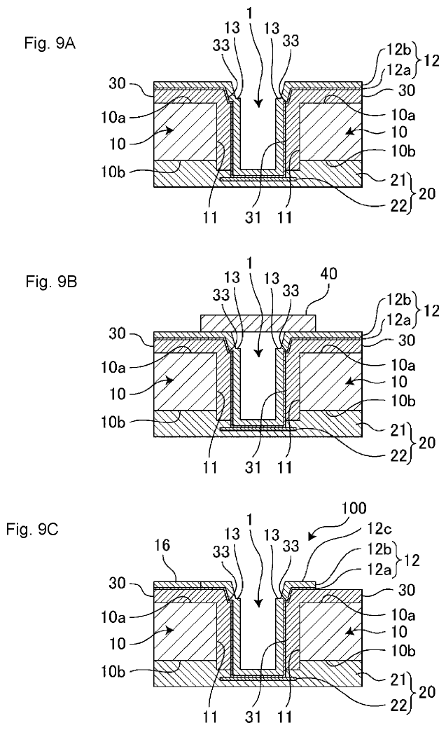

Next, as shown in FIG. 9G, Seed Cu sputtering is performed to form a conductive layer 12a on the upper surface 30a of the insulating film 30, and the inner peripheral surface and the like of the insulating-film through-hole 31. Subsequently, a conductive layer 12b is formed by Cu plating on the conductive layer 12a by Cu plating. Since the conductive layers 12a and 12b are also formed on the copper pads 22 formed on the wiring layer 20, the metal film 12 is electrically connected to the copper pads 22 and the through-electrode 1 is formed.

Next, as shown in FIG. 9H, RDL (Re Distribution Layer: rewiring layer) lithography is performed. Specifically, a resist 40 is applied onto the conductive layer 12b formed on the insulating film 30, and the resist 40 for a predetermined electrode and connection pattern is formed by lithography.

Next, as shown in FIG. 9J, Cu etching (copper etching) is performed to remove unnecessary conductive layers 12a and 12b, thereby forming predetermined electrode patterns 12c and connection conductors 16. After the Cu etching is finished, the resist 40 remaining on the metal film 12 is removed.

Through the steps described above, the semiconductor device 100 having the through-electrode 1 having the resin ISO structure using the ring TSV according to the first or second embodiment can be manufactured.

### 8. Manufacturing Method According to Third Embodiment

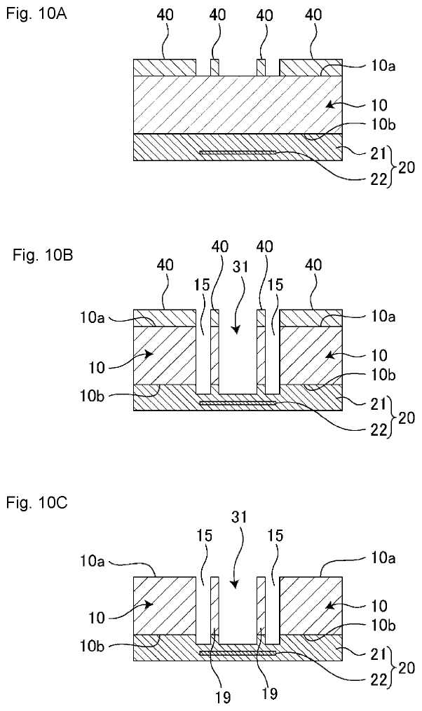

Next, a manufacturing method according to the third embodiment of a method for manufacturing a resin ISO structure using a ring TSV will be described with reference to FIGS. 10 to 12. First, as shown in FIG. 10A, a semiconductor substrate 10 is prepared on which a wiring layer 20 composed of an insulating film, a copper pad, transistor elements, and the like are laminated. Then, the semiconductor substrate is placed on a wafer stage of a semiconductor exposure apparatus for performing lithography. Then, a resist 40 is applied to the upper surface 10a of the semiconductor substrate 10 to form a circular shape in plan view by ring TSV lithography, and a substantially concentric ring is formed on the outer side thereof. In other words, the resist 40 is removed so that the remaining resist 40 forms a substantially cylindrical shape.

Next, as shown in FIG. 10B, ring TSV etching is performed on the portion where the resist 40 has been removed, and the semiconductor substrate 10 is excavated in a substantially double circular shape in plan view to form a ring through-hole 15 and an insulating-film through-hole 31 concentric to the ring through-hole 15. The ring through-hole 15 and the insulating-film through-hole 31 penetrate the semiconductor substrate 10 from the upper surface 10a to the lower surface 10b and are excavated to a predetermined depth of the insulating layer 21. However, it is assumed that the copper pad 22 is not reached. As a result, a substantially cylindrical semiconductor layer 19 is formed between the ring through-hole 15 and the insulating-film through-hole 31.

Next, as shown in FIG. 10C, the resist 40 remaining on the upper surface 10a of the semiconductor substrate 10 is removed.

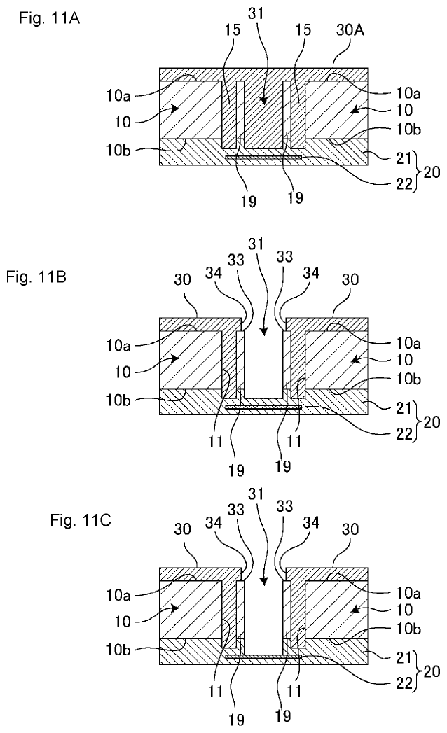

Next, as shown in FIG. 11D, a photosensitive organic material 30A for forming the insulating film 30 is filled in the ring through-hole 15 and the insulating-film through-hole 31 formed in the semiconductor substrate 10 by spin coating or a vacuum laminator and is uniformly applied to the upper surface 10a of the semiconductor substrate 10.

Next, as shown in FIG. 11E, lithography is performed on the photosensitive organic material 30A applied to the upper surface 10a of the semiconductor substrate 10. That is, the organic material 30A filled in the insulating-film through-hole 31 formed by ring TSV etching is removed by lithography. The removed portion on the surface, of the organic material 30A becomes the opening 31a of the insulating-film through-hole 31. Although the peripheral surface of the opening 31a is removed straight, it may be removed in a tapered shape widening upward.

As a result, the inner peripheral surface of the lower stage of the insulating-film through-hole 31 is covered with the semiconductor layer 19. Further, the opening diameter of the insulating-film through-hole 31 opened in the organic material 30A forms a step 33 slightly larger than the inner diameter of the insulating-film through-hole 31 in which the semiconductor layer 19 is interposed. The organic material 30A shaped by lithography then forms the insulating film 30.

Since the organic material 30A is a photosensitive material, it has the advantage that lithography can be performed directly by exposing it to light. The photosensitive material may be of either positive type or negative type.

In the present embodiment, since the inner peripheral surface of the lower stage of the insulating-film through-hole 31 is covered with the semiconductor layer 19, when the insulating-film through-hole 31 is formed with the alignment accuracy of the lithography of the organic material 30A, as shown in FIG. 21, even if the semiconductor layer 19, which is a conductive layer, is excessively excavated, unless the inner peripheral surface of the insulating-film through-hole 31 is excavated, there is no problem in terms of electrical insulation. Therefore, it is possible to suppress the influence of variations in the film thickness of the TSV side walls.

This also applies to the manufacturing method according to the sixth embodiment, which will be described later.

Next, as shown in FIG. 11F, the insulating layer 21 of the wiring layer 20 existing at the bottom of the insulating-film through-hole 31 is excavated by TSV interlayer film etching. When the bottom of the insulating-film through-hole 31 reaches the copper pad 22, the insulating-film through-hole 31, which is a stepped hole, is formed.

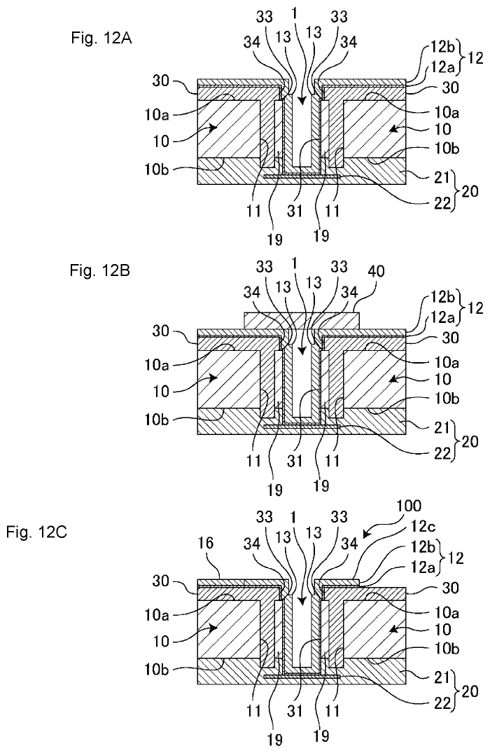

Next, as shown in FIG. 12G, Seed Cu sputtering is performed to form a conductive layer 12a on the upper surface 30a of the insulating film 30 and the inner peripheral surface and the like of the insulating-film through-hole 31.

Subsequently, a conductive layer 12b is formed by Cu plating on the conductive layer 12a by Cu plating. Since the conductive layers 12a and 12b are also formed on the copper pads 22 formed on the wiring layer 20, the metal film 12 is electrically connected to the copper pads 22 and the through-electrode 1 is formed.

Next, as shown in FIG. 12H, RDL lithography is performed. Specifically, a resist 40 is applied onto the conductive layer 12b formed on the insulating film 30, and the resist 40 for a predetermined electrode and connection pattern is formed by lithography.

Next, as shown in FIG. 12J, Cu etching is performed to remove unnecessary conductive layers 12a and 12b, thereby forming predetermined electrode patterns 12c and connection conductors 16.

Through the steps described above, the semiconductor device 100 having the through-electrode 1 having the resin ISO structure using the ring TSV according to the third embodiment can be manufactured.

### 9. Manufacturing Method According to Fourth and Fifth Embodiments

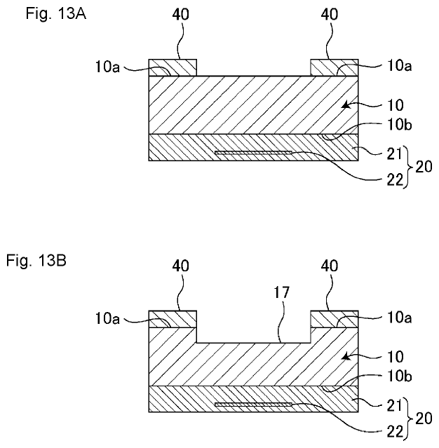

Next, a manufacturing method according to the fourth and fifth embodiments of a method for manufacturing a resin ISO structure using a ring TSV will be described with reference to FIGS. 13 to 16. First, as shown in FIG. 13A, a semiconductor substrate 10 is prepared on which a wiring layer 20 composed of an insulating film, a copper pad, transistor elements, and the like are laminated. Then, the semiconductor substrate is placed on a wafer stage of a semiconductor exposure apparatus for performing lithography. Then, a resist 40 is applied to the upper surface 10a of the semiconductor substrate 10, and the resist 40 is removed in a substantially circular shape in plan view by TSV lithography.

Next, as shown in FIG. 13B, TSV etching is performed on the portion from which the resist 40 has been removed to form an excavation hole 17 having a substantially circular shape in plan view and a predetermined depth in the upper surface 10a of the semiconductor substrate 10.

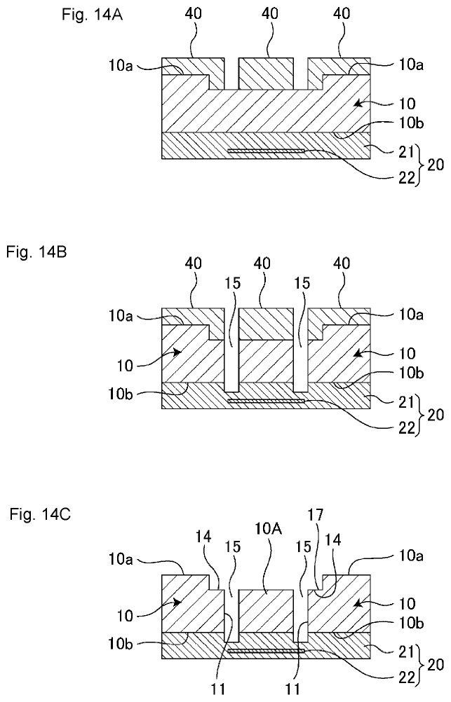

Next, as shown in FIG. 14C, a resist 40 is applied to the excavation hole 17, and the resist 40 in the excavation hole 17 is removed in a substantially ring shape in plan view by ring TSV lithography.

Next, as shown in FIG. 14D, ring TSV etching is performed with the resist 40 applied to form a ring through-hole 15 having a substantially ring shape in plan view in the excavation holes 17 excavated in the semiconductor substrate 10. The ring through-hole 15 formed in this step penetrates the semiconductor substrate 10 from the upper surface 10a to the lower surface 10b and is further excavated to a predetermined depth of the insulating layer 21. However, it is assumed that the copper pad 22 is not reached.

Next, as shown in FIG. 14E, the resist 40 remaining on the upper surface 10a of the semiconductor substrate 10 is removed.

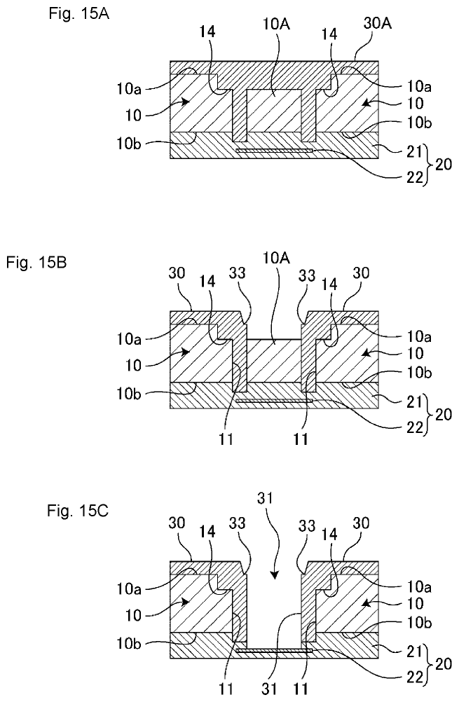

Next, as shown in FIG. 15F, a photosensitive organic material 30A for forming an insulating film 30 is filled in the excavation hole 17 and the ring through-hole 15 excavated in the semiconductor substrate 10 by spin coating or a vacuum laminator, and is uniformly applied to the upper surface 10a of the semiconductor substrate 10.

Next, as shown in FIG. 15G, lithography is performed on the photosensitive organic material 30A applied to the upper surface 10a of the semiconductor substrate 10.

That is, the organic material 30A filled in the excavation hole 17 is removed by lithography to a diameter slightly larger than the inner diameter of the ring through-hole 15. The peripheral surface of the opening 31a of the removed organic material 30A may be removed straight or may be removed in a tapered shape widening upward. This figure shows an example in which a tapered step 33 is provided by lithography. The organic material 30A shaped by lithography then forms the insulating film 30.

Since the organic material 30A is a photosensitive material, it has the advantage that lithography can be performed directly by exposing it to light. The photosensitive material may be of either positive type or negative type.

Next, as shown in FIG. 15H, the substantially cylindrical semiconductor pillar 10A surrounded by the organic material 30A filled in the ring through-hole 15 is removed by TSV etching. Further, the insulating layer 21 of the wiring layer 20 below the semiconductor substrate 10 is excavated to reach the copper pad 22, thereby forming the insulating-film through-hole 31 which is a stepped hole.

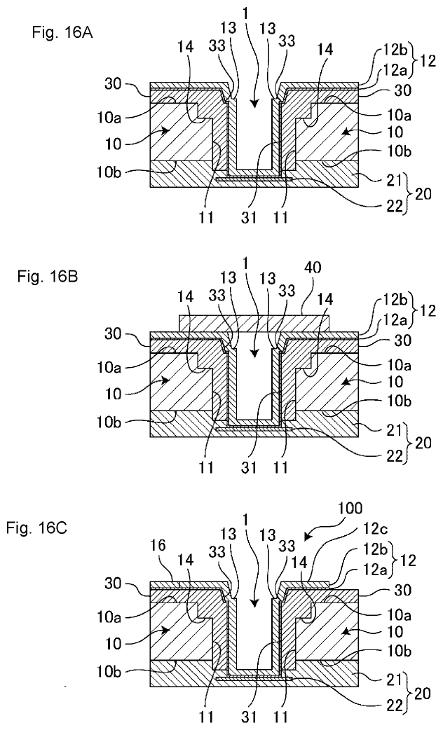

Next, as shown in FIG. 16J, Seed Cu sputtering is performed to form a conductive layer 12a on the upper surface 30a of the insulating film 30 and the inner peripheral surface of the insulating-film through-hole 31. Subsequently, a conductive layer 12b is formed by Cu plating on the conductive layer 12a by Cu plating. Since the conductive layers 12a and 12b are also formed on the copper pads 22 formed on the wiring layer 20, the metal film 12 is electrically connected to the copper pads 22 and the through-electrode 1 is formed.

Next, as shown in FIG. 16K, RDL lithography is performed. Specifically, a resist 40 is applied onto the conductive layer 12b formed on the insulating film 30, and the resist 40 for a predetermined electrode and connection pattern is formed by lithography.

Next, as shown in FIG. 16L, Cu etching is performed to remove unnecessary conductive layers 12a and 12b, thereby forming predetermined electrode patterns 12c and connection conductors 16.

Through the steps described above, the semiconductor device 100 having the through-electrode 1 having the resin ISO structure using the ring TSV according to the fourth or fifth embodiment can be manufactured.

### 10. Manufacturing Method According to Sixth Embodiment

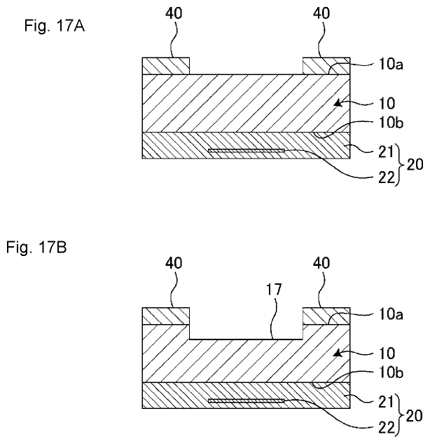

Next, a manufacturing method according to the sixth embodiment of a method for manufacturing a resin ISO structure using a ring TSV will be described with reference to FIGS. 17 to 20. First, as shown in FIG. 17A, a semiconductor substrate 10 is prepared on which a wiring layer 20 composed of an insulating film, a copper pad, transistor elements, and the like are laminated. Then, the semiconductor substrate is placed on a wafer stage of a semiconductor exposure apparatus for performing lithography. Then, a resist 40 is applied to the upper surface 10a of the semiconductor substrate 10, and the resist 40 is removed in a substantially circular shape in plan view by TSV lithography.

Next, as shown in FIG. 17B, TSV etching is performed on the portion from which the resist 40 has been removed to form an excavation hole 17 having a substantially circular shape in plan view and a predetermined depth in the upper surface 10a of the semiconductor substrate 10.

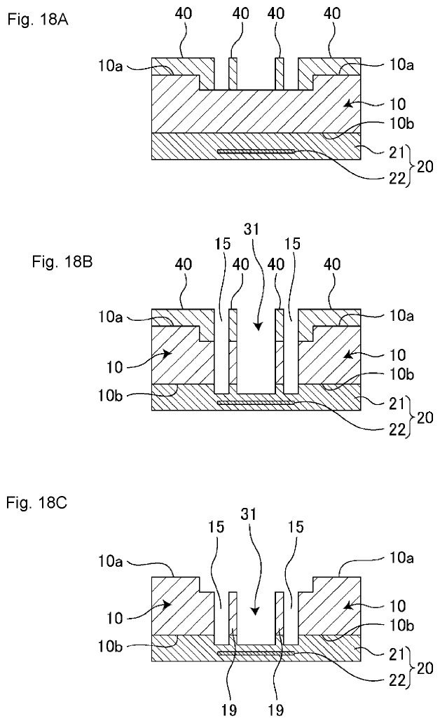

Next, as shown in FIG. 18C, a resist 40 is applied to the excavation hole 17 to form a circular shape in plan view by ring TSV lithography, and a substantially concentric ring is formed on the outer side thereof. In other words, the resist 40 is removed so that the remaining resist 40 forms a substantially cylindrical shape.

Next, as shown in FIG. 18D, ring TSV etching is performed on the portion where the resist 40 has been removed, and the semiconductor substrate 10 is excavated in a substantially double circular shape in plan view to form a ring through-hole 15 and an insulating-film through-hole 31 concentric to the ring through-hole 15. The ring through-hole 15 and the insulating-film through-hole 31 penetrate the semiconductor substrate 10 from the upper surface 10a to the lower surface 10b and are excavated to a predetermined depth of the insulating layer 21. However, it is assumed that the copper pad 22 is not reached. As a result, a substantially cylindrical semiconductor layer 19 is formed between the ring through-hole 15 and the insulating-film through-hole 31.

Next, as shown in FIG. 18E, the resist 40 remaining on the upper surface 10a of the semiconductor substrate 10 is removed.

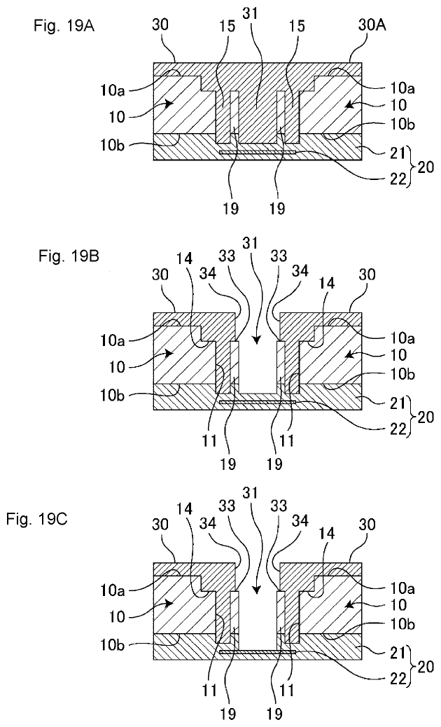

Next, as shown in FIG. 19F, a photosensitive organic material 30A for forming the insulating film 30 is filled in the excavation hole 17, the ring through-hole 15 and the insulating-film through-hole 31 formed in the semiconductor substrate 10 by spin coating or a vacuum laminator and is uniformly applied to the upper surface 10a of the semiconductor substrate 10.

Next, as shown in FIG. 19G, lithography is performed on the photosensitive organic material 30A applied to the upper surface 10a of the semiconductor substrate 10. That is, the organic material 30A filled in the excavation hole 17 is removed by lithography to a diameter slightly larger than the inner diameter of the semiconductor layer 19 formed in a substantially cylindrical shape. The removed portion on the surface, of the organic material 30A becomes the opening 31a of the insulating-film through-hole 31.

Furthermore, the organic material 30A surrounded by the semiconductor layer 19 is removed. As a result, the inner peripheral surface of the lower stage of the insulating-film through-hole 31 is covered with the semiconductor layer 19. Further, the opening diameter of the insulating-film through-hole 31 opened in the organic material 30A forms a step 33 slightly larger than the inner diameter of the insulating-film through-hole 31 in which the semiconductor layer 19 is interposed. The organic material 30A shaped by lithography then forms the insulating film 30.

Since the organic material 30A is a photosensitive material, it has the advantage that lithography can be performed directly by exposing it to light. The photosensitive material may be of either positive type or negative type.

Next, as shown in FIG. 19H, the insulating layer 21 of the wiring layer 20 existing at the bottom of the insulating-film through-hole 31 is excavated by TSV interlayer film etching. When the bottom of the insulating-film through-hole 31 reaches the copper pad 22, the insulating-film through-hole 31, which is a stepped hole, is formed.

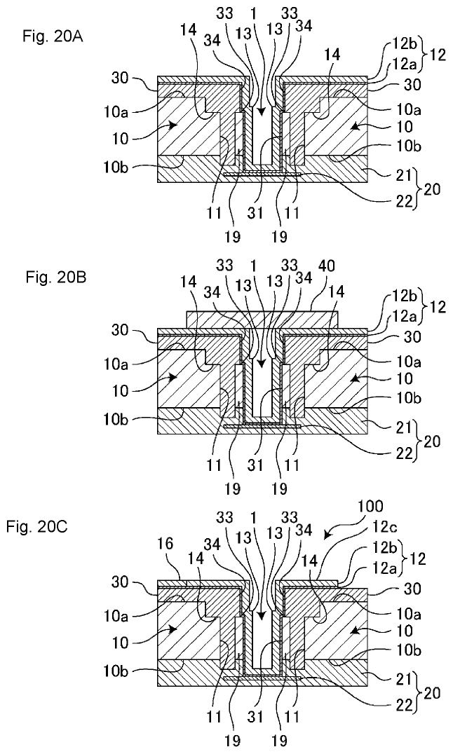

Next, as shown in FIG. 20J, Seed Cu sputtering is performed to form a conductive layer 12a on the upper surface 30a of the insulating film 30 and the inner peripheral surface and the like of the insulating-film through-hole 31. Subsequently, a conductive layer 12b is formed by Cu plating on the conductive layer 12a by Cu plating. Since the conductive layers 12a and 12b are also formed on the copper pads 22 formed on the wiring layer 20, the metal film 12 is electrically connected to the copper pads 22 and the through-electrode 1 is formed.

Next, as shown in FIG. 20K, RDL lithography is performed. Specifically, a resist 40 is applied onto the conductive layer 12b formed on the insulating film 30, and the resist 40 having a predetermined electrode and connection pattern is formed by lithography.

Next, as shown in FIG. 20L, Cu etching is performed to remove unnecessary conductive layers 12a and 12b, thereby forming predetermined electrode patterns 12 and connection conductors 16.

Through the steps described above, the semiconductor device 100 having the through-electrode 1 having the resin ISO structure using the ring TSV according to the sixth embodiment can be manufactured.

Finally, the description of each embodiment described above is an example of the present disclosure, and the present disclosure is not limited to the above-described embodiments. For this reason, it is needless to say that various changes aside from the above-described embodiments can be made according to the design and the like within a scope of not departing from the technical idea of the present disclosure. The advantageous effects described in the present specification are merely exemplary and are not limited, and other advantageous effects may be achieved.

The present technology can also be configured as follows.
(1) A semiconductor device including a through-electrode having a resin ISO structure using a ring TSV, the through-electrode including:
a blind hole formed by excavating a semiconductor substrate to a metal pad laminated on an insulating layer;
a photosensitive insulating film covering an upper surface of the semiconductor substrate and an inner peripheral surface of the blind hole;
and a conductive metal covering the insulating film, wherein the ring TSV is formed such that an opening diameter of an upper stage is slightly different from an inner diameter of a lower stage.
(2) A semiconductor device including a through-electrode having a resin ISO structure using a ring TSV, the through-electrode including:
a blind hole formed by excavating a semiconductor substrate to a metal pad laminated on an insulating layer;
a photosensitive insulating film covering an upper surface of the semiconductor substrate and an inner peripheral surface of the blind hole; and
a conductive metal covering the insulating film, wherein the ring TSV is formed such that a semiconductor layer is interposed between the insulating film and the conductive metal.
(3) The semiconductor device according to (1) or (2), wherein the through-electrode is a stepped hole formed such that an opening diameter of the upper stage is slightly larger than an inner diameter of the lower stage.
(4) The semiconductor device according to (1) or (2), wherein the through-electrode is a hole with eaves formed such that an opening diameter of the upper stage is slightly smaller than an inner diameter of the lower stage.
(5) The semiconductor device according to any one of (1) to (4), wherein the through-electrode is a tapered hole in which the upper stage is tapered.
(6) The semiconductor device according to (1) or (2), wherein the photosensitive insulating film is made of a resin of an organic material or an inorganic material.
(7) A method for manufacturing a semiconductor device having a resin ISO structure using a ring TSV, including:
removing a resist applied to an upper surface of a semiconductor substrate in a substantially ring shape in plan view by ring TSV lithography;
performing ring TSV etching on a portion from which the resist has been removed to form a ring through-hole having a substantially cylindrical shape in plan view;
applying an insulating film to the upper surface of the semiconductor substrate in which the ring through-hole is formed, and filling an insulating film in the ring through-hole;
forming an opening of the ring through-hole into a predetermined shape by lithography;
removing a semiconductor pillar formed by being surrounded by the insulating film filled in the ring through-hole by TSV etching to form a through-hole; and
forming a through-electrode by covering an inner peripheral surface of the through-hole with a conductive material.

### REFERENCE SIGNS LIST

1 Through-electrode
1b Through-electrode bottom
1c Through-electrode corner
10 Semiconductor substrate
10A Semiconductor pillar
10a, 15a Upper surface
10b Lower surface
11 Substrate through-hole
12 Metal film
12a Conductive layer
12b Conductive layer
12c Electrode pattern
13, 14 Step
15 Ring through-hole
16 Connection conductor
17 Excavation hole
19 Semiconductor layer
20 Wiring layer
21 Insulating layer
22 Copper pad
30 Insulating film
30a Upper surface
30A Organic material
31 Insulating-film through-hole
33 Step
34 Eaves
34a Eaves'behind
40 Resist
100 Semiconductor device

1. A semiconductor device comprising a through electrode having a resin ISO structure using a ring TSV, the through-electrode including:
a blind hole formed by excavating a semiconductor substrate to a metal pad laminated on an insulating layer;
a photosensitive insulating film covering an upper surface of the semiconductor substrate and an inner peripheral surface of the blind hole; and
a conductive metal covering the insulating film, wherein the ring TSV is formed such that an opening diameter of an upper stage is slightly different from an inner diameter of a lower stage.

2. A semiconductor device comprising a through electrode having a resin ISO structure using a ring TSV, the through-electrode including:
a blind hole formed by excavating a semiconductor substrate to a metal pad laminated on an insulating layer;
a photosensitive insulating film covering an upper surface of the semiconductor substrate and an inner peripheral surface of the blind hole; and
a conductive metal covering the insulating film, wherein the ring TSV is formed such that a semiconductor layer is interposed between the insulating film and the conductive metal.

3. The semiconductor device according to claim 1, wherein the through-electrode is a tapered hole in which the upper stage is tapered.

4. The semiconductor device according to claim 1, wherein the through electrode is a stepped hole formed such that an opening diameter of the upper stage is slightly larger than an inner diameter of the lower stage.

5. The semiconductor device according to claim 1, wherein the through-electrode is a hole with eaves formed such that an opening diameter of the upper stage is slightly smaller than an inner diameter of the lower stage.

6. The semiconductor device according to claim 1, wherein the photosensitive insulating film is made of a resin of an organic material or an inorganic material.

7. A method for manufacturing a semiconductor device having a resin ISO structure using a ring TSV, comprising:
removing a resist applied to an upper surface of a semiconductor substrate in a substantially ring shape in plan view by ring TSV lithography;
performing ring TSV etching on a portion from which the resist has been removed to form a ring through-hole having a substantially cylindrical shape in plan view;
applying an insulating film to the upper surface of the semiconductor substrate in which the ring through-hole is formed, and filling an insulating film in the ring through-hole;
forming an opening of the ring through-hole into a predetermined shape by lithography;
removing a semiconductor pillar formed by being surrounded by the insulating film filled in the ring through-hole by TSV etching to form a through-hole; and
forming a through-electrode by covering an inner peripheral surface of the through-hole with a conductive material.
